(19) United States
(12) Patent Application Publication
(10) Pub. No.: US 2024/0170413 A1
(43) Pub. Date: May 23, 2024

(54) SEMICONDUCTOR PACKAGE WITH MARKING PATTERNS

(71) Applicant: SAMSUNG ELECTRONICS CO., LTD., Suwon-Si (KR)

(72) Inventors: Jae Gwon JANG, Suwon-si (KR); Jong Youn Kim, Suwon-si (KR); Seok Kyu Choi, Suwon-si (KR)

(73) Assignee: SAMSUNG ELECTRONICS CO., LTD., Suwon-si (KR)

(21) Appl. No.: 18/368,376

(22) Filed: Sep. 14, 2023

(30) Foreign Application Priority Data
Nov. 22, 2022 (KR) 10-2022-0157135
Jan. 4, 2023 (KR) 10-2023-0001122

(51) Int. Cl. H01L 23/544; H01L 25/10; H01L 25/18; H10B 80/00

(52) U.S. Cl. CPC H01L 23/544; H01L 25/105; H01L 25/18; H10B 80/00; H01L 24/16; H01L 2223/54413; H01L 2225/1035; H01L 2225/1058

(57) ABSTRACT

Provided is a semiconductor package including a first wiring structure extending in a first direction and a second crossing the first direction, a first semiconductor chip stacked on the first wiring structure in a third direction different from the first direction and the second direction, a second wiring structure on the first semiconductor chip, the second wiring structure including an insulating layer and a first metal layer on the insulating layer, and a marking plate on the first metal layer, the marking plate including a first marking region and a second marking region different from the first marking region, wherein a shape of the first metal layer corresponding to the first marking region and a shape of the first metal layer corresponding to the second marking region are different from each other, and wherein a shape of an uneven structure in the first marking region and a shape of an uneven structure in the second marking region are different from each other.

### CROSS-REFERENCE TO RELATED APPLICATIONS

This application claims priority from Korean Patent Application No. 10-2022-0157135 filed on Nov. 22, 2022 and Korean Patent Application No. 10-2023-0001122 filed in the Korean Intellectual Property Office on Jan. 4, 2023, the disclosures of which are incorporated herein in their entireties by reference.

### BACKGROUND

### 1. Field

Embodiments of the present disclosure relate to a semiconductor package, and more specifically to a semiconductor package including marking patterns.

### 2. Description of Related Art

With the development of electronic industry, demands for high functionality, high-speed and miniaturization of electronic components have been increased. In response to this trend, a method of stacking and packaging various semiconductor chips on one package wiring structure or a method of stacking a package on another package may be used. For example, a package-in-package (PIP) type semiconductor package or a package-on-package (POP) type semiconductor package may be used.

The POP type semiconductor package may include an interposer for electrical connection between an upper package and a lower package. In this case, a marking pattern in which information of the packages can be recognized may be formed in the interposer.

### BRIEF SUMMARY

Embodiments of the present disclosure provide a semiconductor package having a marking pattern with improved visibility.

The objects of the present disclosure are not limited to those mentioned above and additional objects of the present disclosure, which are not mentioned herein, will be clearly understood by those skilled in the art from the following description of the present disclosure.

According to an aspect of an embodiment, there is provided a semiconductor package including a first wiring structure extending in a first direction and a second crossing the first direction, a first semiconductor chip stacked on the first wiring structure in a third direction different from the first direction and the second direction, a second wiring structure on the first semiconductor chip, the second wiring structure including an insulating layer and a first metal layer on the insulating layer, and a marking plate on the first metal layer, the marking plate including a first marking region and a second marking region different from the first marking region, wherein a shape of the first metal layer corresponding to the first marking region and a shape of the first metal layer corresponding to the second marking region are different from each other, and wherein a shape of an uneven structure in the first marking region and a shape of an uneven structure in the second marking region are different from each other.

According to another aspect of an embodiment, there is provided a semiconductor package including a first wiring structure extending in a first direction and a second direction crossing the first direction, a first semiconductor chip stacked on the first wiring structure in a third direction perpendicular to the first direction and the second direction, a second wiring structure on the first semiconductor chip, the second wiring structure including an insulating layer, a first dummy metal pattern, and a second dummy metal pattern longer than the first dummy metal pattern in the first direction, a first marking plate on the first dummy metal pattern, the first marking plate extending along a surface of the first dummy metal pattern and a surface of the insulating layer, and a second marking plate on the second dummy metal pattern, the second marking plate extending along the surface of the second dummy metal pattern and the surface of the insulating layer, wherein a surface roughness of the first marking plate is greater than a surface roughness of the second marking plate.

According to another aspect of an embodiment, there is provided a semiconductor package including a first semiconductor package and a second semiconductor package on the first semiconductor package, wherein the first semiconductor package includes a first wiring structure extending in a first direction and a second direction crossing the first direction, a first semiconductor chip stacked on the first wiring structure in a third direction different from the first direction and the second direction, a second wiring structure on the first semiconductor chip, the second wiring structure including an insulating layer, a first metal layer on the insulating layer and a second metal layer in the insulating layer, and a marking plate on the first metal layer, the marking plate including a first marking region and a second marking region different from the first marking region, wherein a shape of the first metal layer and a shape of the second metal layer corresponding to the first marking region is different from a shape of the first metal layer and a shape of the second metal layer corresponding to the second marking region, and wherein an uneven structure of the marking plate in the first marking region and an uneven structure of the marking plate in the second marking region are different from each other.

### BRIEF DESCRIPTION OF DRAWINGS

The above and other aspects and features of the present disclosure will become more apparent by describing in detail exemplary embodiments thereof with reference to the attached drawings, in which:

FIGS. 1 and 2 are views illustrating an electronic device according to some embodiments;

FIG. 3 is a view illustrating a semiconductor package and a main board of FIG. 2;

FIG. 4 is an exemplary layout view illustrating a semiconductor package according to some embodiments;

FIG. 5 is a schematic cross-sectional view illustrating a semiconductor package according to some embodiments, which is taken along line I-I′ of FIG. 4;

FIG. 6 is an enlarged view illustrating a region S of FIG. 2;

FIG. 7 is a view illustrating a marking region recognized by a marking pattern recognizer of a semiconductor package according to some embodiments;

FIGS. 8, 9, 11, and 12 are enlarged views illustrating a region S of FIG. 5, and correspond to FIG. 6; and

FIGS. 13, 14, and 15 are schematic cross-sectional views illustrating a semiconductor package according to some embodiments.

### DETAILED DESCRIPTION

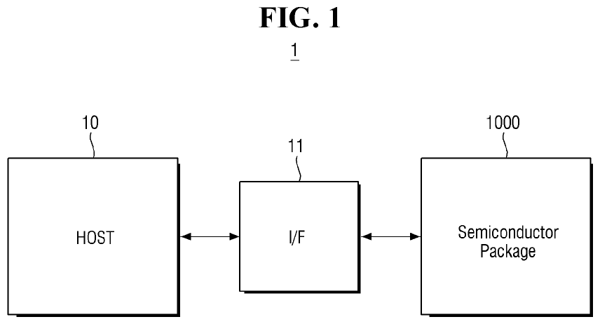

Hereinafter, a semiconductor package according to some embodiments will be described with reference to FIGS. 1 to 7.

Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

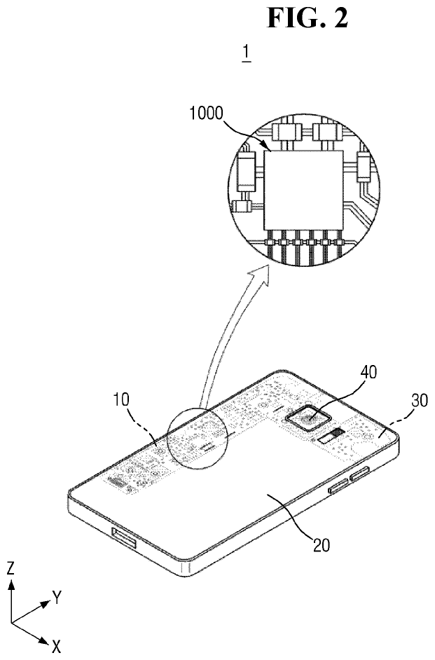

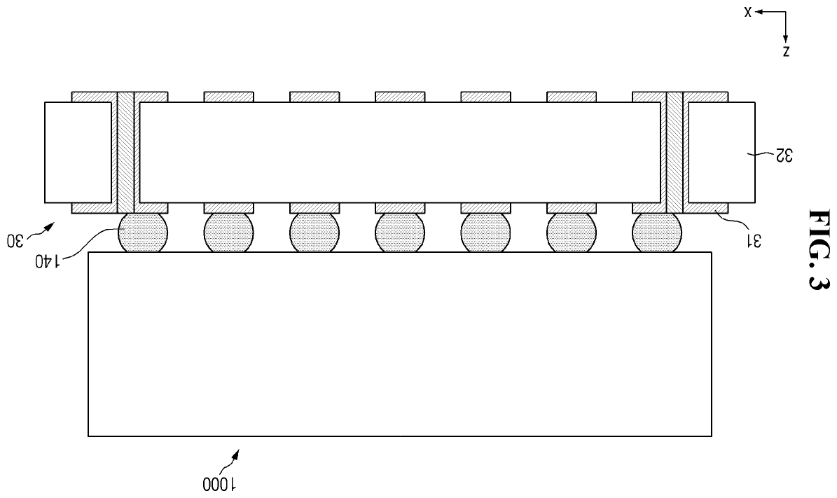

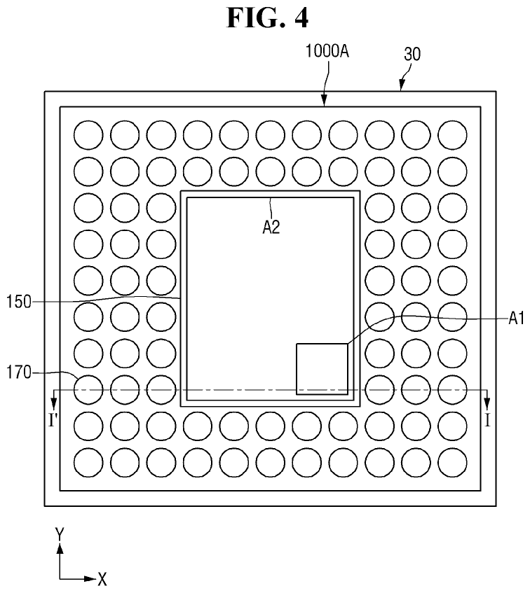

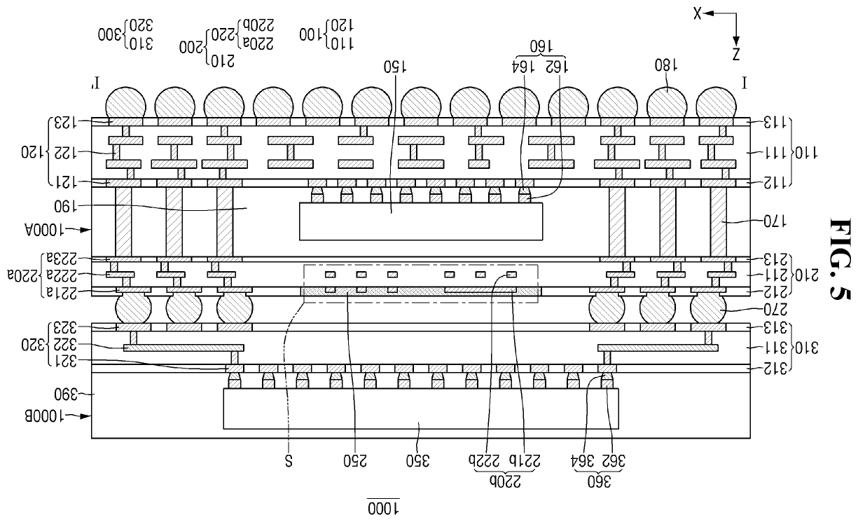

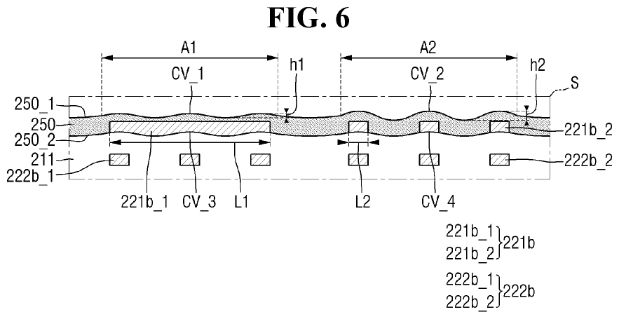

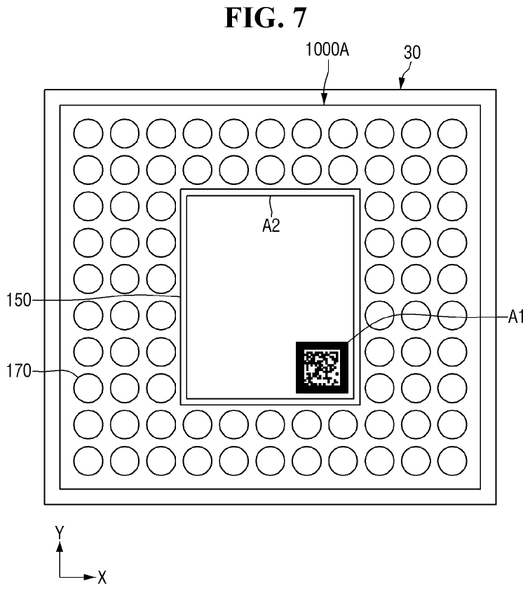

FIGS. 1 and 2 are views illustrating an electronic device according to some embodiments. FIG. 3 is a view illustrating a semiconductor package and a main board of FIG. 2. FIG. 4 is an exemplary layout view illustrating a semiconductor package according to some embodiments. FIG. 5 is a schematic cross-sectional view illustrating a semiconductor package according to some embodiments, which is taken along line I-I′ of FIG. 4. FIG. 6 is an enlarged view illustrating a region S of FIG. 2. FIG. 7 is a view illustrating a marking region recognized by a marking pattern recognizer of a semiconductor package according to some embodiments.

Referring to FIG. 1, an electronic device 1 may include a host 10, an interface 11 and a semiconductor package 1000.

In some embodiments, the host 10 may be connected with the semiconductor package 1000 through the interface 11. For example, the host 10 may transfer a signal to the semiconductor package 1000 to control the semiconductor package 1000. Also, for example, the host 10 may receive the signal from the semiconductor package 1000 to process data included in the signal.

For example, the host 10 may include a central processing unit (CPU), a controller or an application specific integrated circuit (ASIC). In addition, for example, the host 10 may include a memory chip such as a dynamic random access memory (DRAM), a static RAM (SRAM), a phase-change RAM (PRAM), a magneto resistive RAM (MRAM), a ferroelectric RAM (FeRAM) and a resistive RAM (RRAM).

Referring to FIGS. 1 and 2, the electronic device 1 may include a host 10, a body 20, a main board 30, a camera module 40 and a semiconductor package 1000.

The main board 30 may be packaged in the body 20 of the electronic device 1. The host 10, the camera module 40 and the semiconductor package 1000 may be packaged on the main board 30. The host 10, the camera module 40 and the semiconductor package 1000 may be electrically connected to one another by the main board 30. For example, the interface 11 may be implemented by the main board 30.

The host 10 and the semiconductor package 1000 may be electrically connected to each other by the main board 30 to transmit and receive a signal to and from each other.

Referring to FIG. 3, the semiconductor package 1000 may be disposed on the main board 30. For example, a first connection terminal 180 may be disposed on the main board 30. The main board 30 may be connected to the semiconductor package 1000 by the first connection terminal 180.

The main board 30 may be a printed circuit wiring structure (printed circuit board (PCB)), a ceramic wiring structure, a glass wiring structure and an interposer wiring structure, but embodiments are not limited thereto. For convenience of description, it is assumed that the main board 30 is a printed circuit wiring structure.

The main board 30 may include a connection structure 31 and a core 32. The core 32 may include a copper clad laminate (CCL), a Prepreg (PPG), an Ajinomoto Build-up Film (ABF), epoxy, polyimide and the like. The connection structure 31 may include at least one of copper (Cu), aluminum (Al), silver (Ag), tin (Sn), gold (Au), nickel (Ni), lead (Pb), titanium (Ti) or their alloy, but is not limited thereto.

The core 32 may be disposed at the center of the main board 30, and the connection structure 31 may be disposed at upper and lower portions of the core 32. The connection structure 31 may be disposed to be exposed to upper and lower portions of the main board 30.

The connection structure 31 may be also disposed to pass through the core 32. The connection structure 31 may electrically connect elements, which are in contact with the main board 30, with each other. For example, the connection structure 31 may electrically connect the semiconductor package 1000 with the host 10. For example, the connection structure 31 may electrically connect the semiconductor package 1000 with the host 10 through the first connection terminal 180.

Referring to FIG. 5, the semiconductor package according to some embodiments may include a first semiconductor package 1000A and a second semiconductor package 1000B on the first semiconductor package 1000A.

The first semiconductor package 1000A includes a first wiring structure 100, a first semiconductor chip 150, a second wiring structure 200 and a marking plate 250, and may further include a first bump 160 and a first mold layer 190.

The first wiring structure 100 may be a wiring structure for a package. For example, the first wiring structure 100 may be a printed circuit wiring structure (printed circuit board (PCB)) or a ceramic wiring structure. According to another embodiment, the first wiring structure 100 may be a wiring structure for a wafer level package (WLP) manufactured at a wafer level. The first wiring structure 100 may include a lower surface and an upper surface, which are opposite to each other.

The first wiring structure 100 includes a first insulating layer 110 and a first metal layer 120. The first insulating layer 110 may include a first substrate 111, a first lower passivation layer 113 and a first upper passivation layer 112. The first metal layer 120 may include a first lower pad 123, a first connection pad 122 and a first upper pad 121.

The first substrate 111 may be, for example, a printed circuit board (PCB) or a ceramic substrate, but embodiments are not limited thereto.

When the first substrate 111 is a printed circuit board, the first substrate 111 may be made of at least one material selected from a phenol resin, an epoxy resin or polyimide. For example, the first substrate 111 may include at least one material selected from FR4, tetrafunctional epoxy, polyphenylene ether, epoxy/polyphenylene oxide, bismaleimide triazine (BT), thermount, cyanate ester, polyimide or liquid crystal polymer.

A surface of the first substrate 111 may be covered by a solder resist. For example, the first lower passivation layer 113 and the first upper passivation layer 112, which are formed on the surface of the first substrate 111, may be solder resists, but embodiments are not limited thereto.

The first metal layer 120 may be disposed inside the first insulating layer 110. The first metal layer 120 may include a first connection pad 122 for electrically connecting the first lower pad 123 with the first upper pad 121. The first connection pad 122 may include a plurality of wires and a plurality of vias connecting the wires.

The first substrate 111 is shown as a single layer, but embodiments are not limited thereto. For example, the first substrate 111 may be composed of multiple layers to form a first connection pad 122 of multiple layers.

In some embodiments, the first connection terminal 180 may be formed on a lower surface of the first wiring structure 100. The first connection terminal 180 may be attached to the first lower pad 123. The first connection terminal 180 may be, for example, spherical or elliptical, but is not limited thereto. The first connection terminal 180 may include at least one of tin (Sn), indium (In), lead (Pb), zinc (Zn), nickel (Ni), gold (Au), silver (Ag), copper (Cu), antimony (Sb), bismuth (Bi) or their combination, but embodiments are not limited thereto.

The first connection terminal 180 may electrically connect the first wiring structure 100 with an external device. Therefore, the first connection terminal 180 may provide an electrical signal to the first wiring structure 100 or provide the electrical signal provided from the first wiring structure 100 to the external device.

The first upper passivation layer 112 and the first upper pad 121 may be formed on an upper surface of the first substrate 111. The first upper passivation layer 112 may cover the upper surface of the first substrate 111 and expose the first upper pad 121.

The first lower passivation layer 113 and the first lower pad 123 may be formed on a lower surface of the first substrate 111. The first lower passivation layer 113 may cover the lower surface of the first substrate 111 and expose the first lower pad 123.

In some embodiments, the first upper pad 121 may be electrically connected to the first lower pad 123. For example, the first upper pad 121 may be electrically connected to the first lower pad 123 by being connected to the first connection pad 122.

The first lower passivation layer 113 and the first upper passivation layer 112 may include, for example, a photoimageable dielectric (PID) material, but is not limited thereto.

The first metal layer 120 may include at least one of copper (Cu), aluminum (Al), silver (Ag), tin (Sn), gold (Au), nickel (Ni), lead (Pb), titanium (Ti) or their combination, but is not limited thereto.

The first semiconductor chip 150 may be disposed on the first wiring structure 100. For example, the first semiconductor chip 150 may be packaged on an upper surface of the first wiring structure 100. The first semiconductor chip 150 may be an integrated circuit (IC) in which hundreds to millions of semiconductor elements are integrated into one chip. For example, the first semiconductor chip 150 may be an application processor (AP) such as a central processing unit (CPU), a graphic processing unit (GPU), a field programmable gate array (FPGA), a digital signal processor, an encryption processor, a microprocessor and a microcontroller, but is not limited thereto. For example, the first semiconductor chip 150 may be a logic chip such as an analog-digital converter (ADC) or an application-specific IC (ASIC), or may be a memory chip such as a volatile memory (e.g., DRAM) or a non-volatile memory (e.g., ROM or flash memory). In addition, the first semiconductor chip 150 may be composed of a combination of the logic chip and the memory chip.

Although only one first semiconductor chip 150 is shown as being formed on the first wiring structure 100, this is for convenience of description. For example, a plurality of first semiconductor chips 150 may be formed side by side in a horizontal direction (x-axis direction) on the first wiring structure 100, or a plurality of first semiconductor chips 150 may be sequentially stacked in a vertical direction (z-axis direction) on the first wiring structure 100.

In some embodiments, the first semiconductor chip 150 may be packaged on the first wiring structure 100 by a flip chip bonding method. For example, the first bump 160 may be formed between the upper surface of the first wiring structure 100 and the lower surface of the first semiconductor chip 150. The first bump 160 may electrically connect the first wiring structure 100 with the first semiconductor chip 150.

The first bump 160 may include, for example, a first pillar layer 162 and a first solder layer 164.

The first pillar layer 162 may be protruded from the lower surface of the first semiconductor chip 150. The first pillar layer 162 may include, for example, copper (Cu), a copper alloy, nickel (Ni), palladium (Pd), platinum (Pt), gold (Au), cobalt (Co) and their combination, but is not limited thereto.

The first solder layer 164 may connect the first pillar layer 162 with the first wiring structure 100. For example, the first solder layer 164 may be connected to and in contact with a portion of the first upper pad 121. The first solder layer 164 may be, for example, spherical or elliptical, but is not limited thereto. The first solder layer 164 may include, for example, tin (Sn), indium (In), bismuth (Bi), antimony (Sb), copper (Cu), silver (Ag), zinc (Zn), lead (Pb) or their combination, but is not limited thereto.

The second wiring structure 200 may be disposed between the first wiring structure 100 and a third wiring structure 300 that will be described later. For example, the second wiring structure 200 may be disposed on the upper surface of the first wiring structure 100 and the first semiconductor chip 150. In some embodiments, the second wiring structure 200 may be an interposer. The second wiring structure 200 may facilitate connection between the first wiring structure 100 and the third wiring structure 300. In addition, the second wiring structure 200 may prevent a warpage phenomenon from occurring between the first wiring structure 100 and the third wiring structure 300.

The second wiring structure 200 may include a lower surface and an upper surface, which are opposite to each other. For example, the lower surface of the second wiring structure 200 may face the upper surface of the first wiring structure 100, and the upper surface of the second wiring structure 200 may face a lower surface of the third wiring structure 300.

The second wiring structure 200 may be spaced apart from the first wiring structure 100. In addition, the second wiring structure 200 may be spaced apart from the first semiconductor chip 150.

The second wiring structure 200 may include a second insulating layer 210 and a second metal layer 220. The second insulating layer 210 may include a second lower passivation layer 213, a second substrate 211 and a second upper passivation layer 212.

The second substrate 211 may be, for example, a printed circuit board (PCB), but embodiments are not limited thereto. In some embodiments, the second substrate 211 may include a dielectric material.

The second substrate 211 is shown as a single layer, embodiments are not limited thereto. For example, the second substrate 211 may be composed of multiple layers to form a (2a)th metal pad 222a and a (2b)th metal pad 222b, which are formed of multiple layers and will be described later.

The second upper passivation layer 212 may be formed on an upper surface of the second substrate 211. The second upper passivation layer 212 may cover the upper surface of the second substrate 211 and expose a (2a)th upper pad 221a and a (2b)th upper pad 221b, which will be described later.

The second lower passivation layer 213 may be formed on a lower surface of the second substrate 211. The second lower passivation layer 213 may cover the lower surface of the second substrate 211 and expose a (2a)th lower pad 223a that will be described later.

The second lower passivation layer 213 and the second upper passivation layer 212 may include, for example, a photoimageable dielectric (PID), but are not limited thereto.

The second metal layer 220 may include a connection metal layer 220a and a dummy metal layer 220b.

The connection metal layer 220a may be disposed inside the second insulating layer 210. The connection metal layer 220a may include a (2a)th lower pad 223a, a (2a)th metal pad 222a and a (2a)th upper pad 221a.

The (2a)th metal pad 222a may electrically connect the (2a)th lower pad 223a with the (2a)th upper pad 221a. The (2a)th metal pad 222a may include a plurality of wires and a plurality of vias connecting the wires.

The dummy metal layer 220b may be disposed on the second insulating layer 210. The dummy metal layer 220b may include a (2b)th upper pad 221b and a (2b)th metal pad 222b.

The second metal layer 220 may include at least one of copper (Cu), aluminum (Al), silver (Ag), tin (Sn), gold (Au), nickel (Ni), lead (Pb), titanium (Ti) or their combination, but is not limited thereto.

The dummy metal layer 220b may not electrically connect the first wiring structure 100 with the third wiring structure 300.

The dummy metal layer 220b will be described in more detail with reference to FIG. 6.

The marking plate 250 may include marking patterns disposed on the first semiconductor chip 150, indicating identification information. In this case, the identification information may include various kinds of information having traceability of a corresponding semiconductor package, for example, a process number, a manufacturing company, a manufacturing date, a product name, a product type and a combination thereof. The marking patterns may include two-dimensional (2D) barcodes, which are more indirect identification means, as well as symbols, numbers and characters. For example, the 2D barcodes may be implemented in various types such as a data matrix, a QR code and the like.

The marking plate 250 is disposed on the (2b)th upper pad 221b, and may include a first marking region A1 and a second marking region A2 that are different from each other. The first marking region A1 may be a region that includes two-dimensional barcodes, and the second marking region A2 may be a region that includes a marking pattern composed of symbols, numbers, characters and the like. In some embodiments, the first and second marking regions A1 and A2 may be referred to as first and second marking plates, respectively.

An area of the first marking region A1 may be greater than that of the second marking region A2. For example, in first and second directions (X-axis and Y-axis directions), a length of the first marking region A1 may be 1 mm and a length of the second marking region A2 may be 3 mm, but embodiments are not limited thereto.

A recess exposing at least a portion of the second upper passivation layer 212 may be formed in the second wiring structure 200. The marking plate 250 may be formed inside the recess.

Referring to FIG. 6, the (2b)th upper pad 221b may be disposed on the second substrate 211. The (2b)th upper pad 221b may include a (2b_1)th upper pad 221b_1 corresponding to the first marking region A1 and a (2b_2)th upper pad 221b_2 corresponding to the second marking region A2, below the first marking region A1.

The first marking region A1 may be formed on the (2b_1) upper pad 221b_1 along surfaces of the (2b_1)th upper pad 221b_1 and the second substrate 211 to correspond to the surfaces of the (2b_1)th upper pad 221b_1 and the second substrate 211. The second marking region A2 may be formed on the (2b_2)th upper pad 221b_2 along surfaces of the (2b_2)th upper pad 221b_2 and the second substrate 211 to correspond to the surfaces of the (2b_2)th upper pad 221b_2 and the second substrate 211.

Shapes of the (2b_1)th upper pad 221b_1 and the (2b_2)th upper pad 221b_2 may be different from each other. For example, in the first direction (X-axis direction), a length L1 of the (2b_1)th upper pad 221b_1 may be longer than a length L2 of the (2b_2)th upper pad 221b_2.

In addition, a plurality of (2b_2)th upper pads 221b_2 may be formed to be more than the number of (2b_1)th upper pads 221b_1. In this case, the length L1 of the (2b_1)th upper pad 221b_1 may be longer than the length L2 of each of the plurality of (2b_2)th upper pads 221b_2. The respective (2b_2)th upper pads 221b_2 may be spaced apart from each other.

The marking plate 250 may include an upper surface 250_1 and a lower surface 250_2, which face each other. The upper surface 250_1 of the first marking region A1 of the marking plate 250 may have a first uneven structure to correspond to the (2b_1)th upper pad 221b_1. The upper surface 250_1 of the second marking region A2 of the marking plate 250 may have a second uneven structure to correspond to the (2b_2)th upper pad 221b_2.

A first convex portion CV_1 may be formed on the upper surface 250_1 of the first marking region A1 of the marking plate 250, which corresponds to the (2b_1)th upper pad 221b_1.

A plurality of second convex portions CV_2 may be formed on the upper surface 250_1 of the second marking region A2 of the marking plate 250, which corresponds to each of the plurality of (2b_2)th upper pads 221b_2.

Also, the upper surface 250_1 of the first marking region A1 of the marking plate 250 may be formed to have a first height difference h1 between the highest point and the lowest point in the first marking region A1 in the third direction, and the upper surface 250_1 of the second marking region A2 of the marking plate 250 may be formed to have a second height difference h2, between the highest point and the lowest point in the second marking region A2 in the third direction, that is greater than the first height difference h1.

For example, the first uneven structure and the second uneven structure may be formed in their respective shapes different from each other. In this case, surface roughness of the upper surface 250_1 of the second marking region A2 may be greater than that of the upper surface 250_1 of the first marking region A1.

For example, surface roughness of an upper surface 300a of the marking plate 250 disposed in the second marking region A2 may be five times or more of surface roughness of the upper surface 300a of the marking plate 250 disposed in the first marking region A1.

For example, the surface roughness of the upper surface 250_1 of the second marking region A2 may be 4500 Å and the surface roughness of the upper surface 250_1 of the first marking region A1 may be 459 Å, but embodiments are not limited thereto. In the present disclosure, the surface roughness may be a maximum height roughness Ry.

The (2b)th metal pad 222b may be disposed in the second substrate 211. The (2b)th metal pad 222b may be disposed below the (2b)th upper pad 221b. The (2b)th metal pad 222b may include a (2b_1)th metal pad 222b_1 corresponding to the first marking region A1 and a (2b_2)th metal pad 222b_2 corresponding to the second marking region A2.

Each of the (2b_1)th metal pad 222b_1 and the (2b_2)th metal pad 222b_2 may be formed in a plural number. Each of the plurality of (2b_1)th metal pads 222b_1 may be spaced apart from each of the plurality of (2b_2)th metal pads 222b_2.

The upper surface of the second substrate 211 may have an uneven structure to correspond to each of the (2b_1)th metal pad 222b_1 and the (2b_2)th metal pad 222b_2.

In detail, a third convex portion CV_3 and a fourth convex portion CV 4 may be formed on the upper surface of the second substrate 211 to correspond to the (2b_1)th metal pad 222b_1 and the (2b_2)th metal pad 222b_2, respectively.

In some embodiments, different uneven structures may be formed in the first and second marking regions A1 and A2 by varying the shape and/or arrangement structure of the metal pads disposed below the marking plate 250. Therefore, the surface roughness of the first marking region A1 may be formed different from the surface roughness of the second marking region A2.

In the related art, identification information may be obtained through a process of emitting light to the marking plate 250 and converting the light into a digital signal based on a difference in the amount of light reflection. In some embodiments, the first marking region A1, which includes two-dimensional barcodes, is formed to have surface roughness different from that of the second marking region A2, whereby diffused reflection of light in the first marking region A1 may be minimized to make sure of visibility of the marking pattern as shown in FIG. 7.

The marking plate 250, which includes the first and second marking regions A1 and A2, may include a metal material. As another example, the marking plate 250, which includes the first and second marking regions A1 and A2, may include an insulating material.

A first connection member 170 may be interposed between the first wiring structure 100 and the second wiring structure 200. The first connection member 170 may be in contact with the upper surface of the first wiring structure 100 and the lower surface of the second wiring structure 200. For example, the first connection member 170 may be in contact with the first upper pad 121 of the first wiring structure 100 and the (2a)th metal pad 222a of the second wiring structure 200. Therefore, the first connection member 170 may electrically connect the first wiring structure 100 with the second wiring structure 200.

The first connection member 170 may be in the form of a through silicon via (TSV) passing through the first mold layer 190, which will be described later, but is not limited thereto.

The first connection member 170 may include, for example, tin (Sn), indium (In), bismuth (Bi), antimony (Sb), copper (Cu), silver (Ag), zinc (Zn), lead (Pb) and their combination, but is not limited thereto.

The first mold layer 190 may be formed on the first wiring structure 100. The first mold layer 190 may fill a space between the first wiring structure 100 and the second wiring structure 200. Therefore, the first mold layer 190 may cover the first wiring structure 100, the first semiconductor chip 150, the first bump 160 and the first connection member 170 to protect them.

The first mold layer 190 may include, for example, an insulating polymer material such as an epoxy molding compound (EMC). The first mold layer 190 may include a thermosetting resin such as an epoxy resin, a thermoplastic resin such as polyimide, or a resin including a reinforcing material, such as a filler, in the thermosetting resin and the thermoplastic resin, for example, ABF, FR-4, BT resin, etc.

The filler may be at least one selected from a group consisting of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and zircon calcium (CaZrO₃), but the filler's material is not limited thereto, and may include a metal material and/or an organic material.

The semiconductor package according to some embodiments may further include a second semiconductor package 1000B that includes a second semiconductor chip 350 packaged on the third wiring structure 300 on the first semiconductor package 1000A. The second semiconductor package 1000B may further include a third wiring structure 300, a second bump 360, a second semiconductor chip 350 and a second mold layer 390.

The third wiring structure 300 may be disposed on the upper surface of the second wiring structure 200. The third wiring structure 300 may be a wiring structure for a package. For example, the third wiring structure 300 may be a printed circuit wiring structure (printed circuit board (PCB)) or a ceramic wiring structure. According to another embodiment, the third wiring structure 300 may be a wiring structure for a wafer level package (WLP) manufactured at a wafer level. The third wiring structure 300 may include a lower surface and an upper surface, which are opposite to each other.

The third wiring structure 300 includes a third insulating layer 310 and a third metal layer 320. The third insulating layer 310 may include a third substrate 311, a third lower passivation layer 313 and a third upper passivation layer 312. The third metal layer 320 may include a third lower pad 323, third connection pads 321, and a third connection pad 322 between the third lower pad 323 and the third upper pad 321.

The third substrate 311 may be, for example, a printed circuit board (PCB) or a ceramic substrate, but embodiments are not limited thereto.

When the third substrate 311 is a printed circuit board, the third substrate 311 may be made of at least one material selected from a phenol resin, an epoxy resin or polyimide. For example, the third substrate 311 may include at least one material selected from FR4, tetrafunctional epoxy, polyphenylene ether, epoxy/polyphenylene oxide, bismaleimide triazine (BT), thermount, cyanate ester, polyimide or liquid crystal polymer.

A surface of the third substrate 311 may be covered by a solder resist. For example, the third lower passivation layer 313 and the third upper passivation layer 312, which are formed on the surface of the third substrate 311, may be solder resists, but embodiments are not limited thereto.

The third metal layer 320 may be disposed inside the third insulating layer 310. The third metal layer 320 may include a third connection pad 322 for electrically connecting the third lower pad 323 with the third upper pad 321. The third connection pad 322 may include a plurality of wires and a plurality of vias connecting the wires.

The third insulating layer 310 is shown as a single layer, but embodiments are not limited thereto. For example, the third insulating layer 310 may be composed of multiple layers to form a third metal layer 320 of multiple layers.

The third upper passivation layer 312 and the third upper pad 321 may be formed on an upper surface of the third substrate 311. The third upper passivation layer 312 may cover the upper surface of the third substrate 311 and expose the third upper pad 321.

The third lower passivation layer 313 and the third lower pad 323 may be formed on a lower surface of the third substrate 311. The third lower passivation layer 313 may cover the lower surface of the third substrate 311 and expose the third lower pad 323.

In some embodiments, the third upper pad 321 may be electrically connected to the third lower pad 323. For example, the third upper pad 321 may be electrically connected to the third lower pad 323 by being in contact with the third connection pad 322.

The third lower passivation layer 313 and the third upper passivation layer 312 may include, for example, a photoimageable dielectric (PID) material, but is not limited thereto.

A second connection terminal 270 may be interposed between the second wiring structure 200 and the third wiring structure 300. The second connection terminal 270 may be in contact with the upper surface of the second wiring structure 200 and the lower surface of the third wiring structure 300. The second connection member 270 may electrically connect the second wiring structure 200 with the third wiring structure 300. For example, the second connection terminal 270 may be in contact with the (2a)th upper pad 221a of the second wiring structure 200 and the third lower pad 323 of the third wiring structure 300.

The second connection terminal 270 may be, for example, spherical or elliptical, but is not limited thereto. The second connection terminal 270 may include at least one of tin (Sn), indium (In), lead (Pb), zinc (Zn), nickel (Ni), gold (Au), silver (Ag), copper (Cu), antimony (Sb), bismuth (Bi) or their combination, but embodiments are not limited thereto.

The second semiconductor chip 350 may be disposed on the third wiring structure 300. For example, the second semiconductor chip 350 may be packaged on an upper surface of the third wiring structure 300. The second semiconductor chip 350 may be an integrated circuit (IC) in which hundreds to millions of semiconductor elements are integrated into one chip.

In some embodiments, the first semiconductor chip 150 may be a logic chip such as an application processor (AP), and the second semiconductor chip 350 may be a memory chip such as a volatile memory (e.g., DRAM) or a non-volatile memory (e.g., ROM or flash memory).

Although only one second semiconductor chip 350 is shown as being formed on the third wiring structure 300, embodiments are not limited thereto. For example, a plurality of second semiconductor chips 350 may be formed side by side on the third wiring structure 300, or a plurality of second semiconductor chips 350 may be sequentially stacked on the third wiring structure 300.

In some embodiments, the second semiconductor chip 350 may be packaged on the third wiring structure 300 by a flip chip bonding method. For example, the second bump 360 may be formed between the upper surface of the first wiring structure 100 and the lower surface of the second semiconductor chip 350. The second bump 360 may electrically connect the third wiring structure 300 with the second semiconductor chip 350.

The second bump 360 may include, for example, a second pillar layer 362 and a second solder layer 364. Since the second pillar layer 362 and the second solder layer 364 may be similar to the first pillar layer 162 and the first solder layer 164, their detailed description will be omitted.

In some embodiments, the second mold layer 390 may be formed on the third wiring structure 300. The second mold layer 390 may cover the third wiring structure 300, the second semiconductor chip 350 and the second bump 360 to protect them. The second mold layer 390 may include, for example, an insulating polymer material such as EMC, but is not limited thereto.

The semiconductor package according to some embodiments may further include a passive element formed below the first wiring structure 100. The passive element may be packaged on the first wiring structure 100 by a flip chip bonding method.

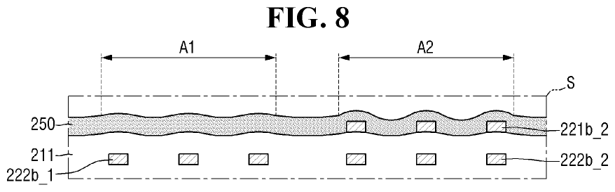

FIGS. 8 to 12 are enlarged views illustrating a region S of FIG. 5, and correspond to FIG. 6. For convenience of description, the following description will be based on differences from the semiconductor packages shown in FIGS. 1 to 7.

Referring to FIG. 8, the (2b_1)th upper pad 221b_1 may not be formed in the first marking region A1. For example, as the (2b_1)th upper pad 221b_1 is not disposed in the first marking region A1, the surface roughness of the first marking region A1 may be smaller than the surface roughness of the second marking region A2.

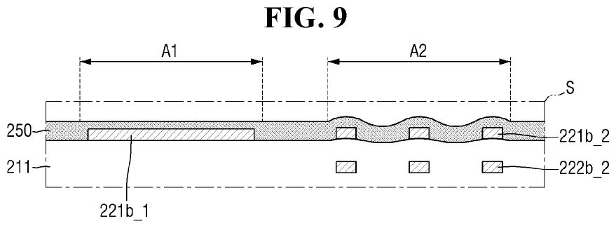

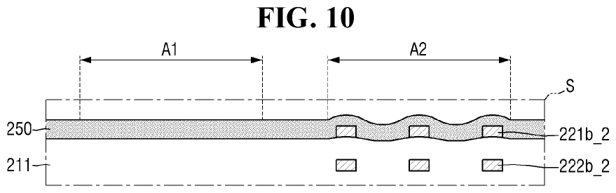

Referring to FIG. 9, the (2b_1)th upper pad 221b_1 may be formed in the first marking region A1, and the (2b_1)th metal pad 222b_1 may not be formed in the first marking region A1. Therefore, the surface roughness of the first marking region A1 may be smaller than the surface roughness of the second marking region A2.

Referring to FIG. 10, the (2b_1)th upper pad 221b_1 and the (2b_1)th metal pad 222b_1 may not be formed in the first marking region A1. Therefore, the surface roughness of the first marking region A1 may be smaller than the surface roughness of the second marking region A2.

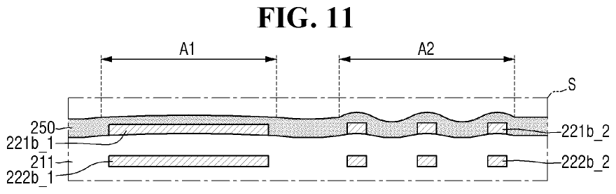

Referring to FIG. 11, the (2b_1)th upper pad 221b_1 and the (2b_1)th metal pad 222b_1, which are longer in length than the (2b_2)th upper pad 221b_2 and the (2b_2)th metal pad 222b_2, may be formed in the first marking region A1. Therefore, the surface roughness of the first marking region A1 may be smaller than the surface roughness of the second marking region A2.

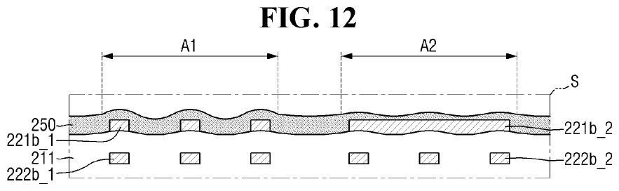

Referring to FIG. 12, a plurality of (2b_1)th upper pads 221b_1 may be formed in the first marking region A1, and one (2b_2)th upper pad 221b_2 having a longer length than the (2b_1)th upper pad 221b_1 may be formed in the second marking region A2. Therefore, the surface roughness of the second marking region A2 may be smaller than that of the first marking region A1.

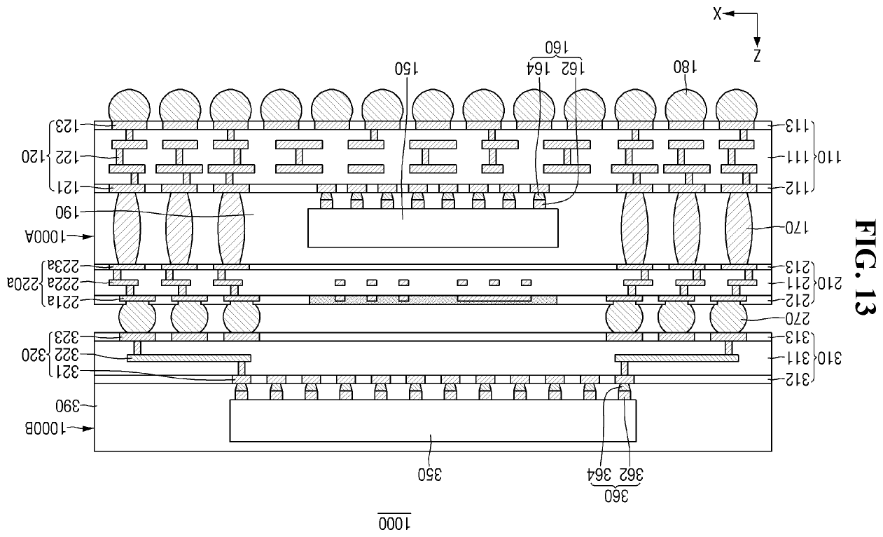

FIGS. 13 to 15 are schematic cross-sectional views illustrating a semiconductor package according to some embodiments. For convenience of description, the following description will be based on differences from the semiconductor packages shown in FIGS. 1 to 12.

Referring to FIG. 13, the first connection member 170 may be, for example, spherical or elliptical. The first connection member 170 may include, for example, at least one of tin (Sn), indium (In), lead (Pb), zinc (Zn), nickel (Ni), gold (Au), silver (Ag), copper (Cu), antimony (Sb), bismuth (Bi) or their combination, but embodiments are not limited thereto.

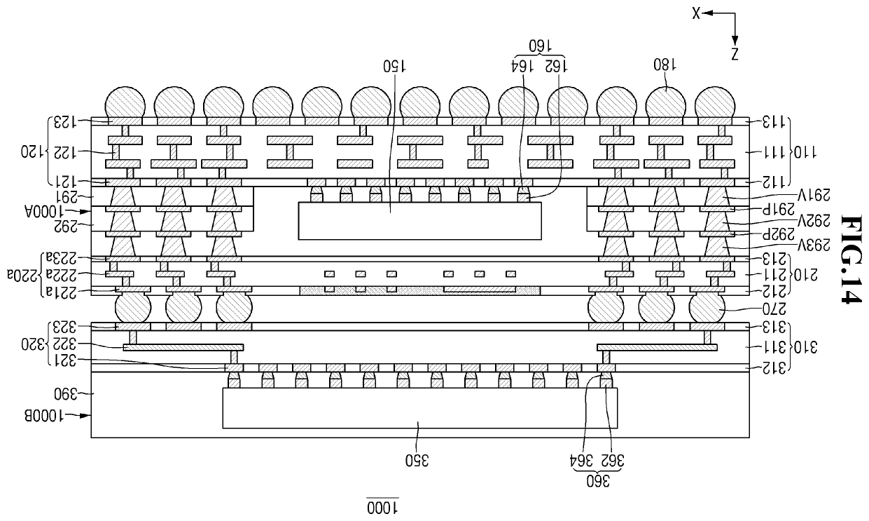

Referring to FIG. 14, the semiconductor package according to some embodiments of the present disclosure may include a third mold layer 291, a fourth mold layer 292, a first connection via 291V, a second connection via 292V, and a third connection via 293V, a first connection pad 291P and a second connection pad 292P between the first wiring structure 100 and the second wiring structure 200.

The third mold layer 291 may be disposed on the upper surface of the first wiring structure 100. The third mold layer 291 may be disposed in the periphery of a sidewall of the first semiconductor chip 150. The third mold layer 291 may be spaced apart from the first semiconductor chip 150.

The fourth mold layer 292 may be disposed on the third mold layer 291. The fourth mold layer 292 may be disposed in the periphery of the sidewall of the first semiconductor chip 150. The fourth mold layer 292 may be spaced apart from the first semiconductor chip 150.

Each of the third mold layer 291 and the fourth mold layer 292 may include an insulating material. Each of the third mold layer 291 and the fourth mold layer 292 may include a material different from that of the first mold layer 190, but embodiments are not limited thereto.

The first connection pad 291P may be disposed on an upper surface of the third mold layer 291. The second connection pad 292P may be disposed on an upper surface of the fourth mold layer 292. Each of the first connection pad 291P and the second connection pad 292P may include a conductive material.

The first connection via 291V may pass through the third mold layer 291. The first connection via 291V may be connected to each of the first upper pad 121 and the first connection pad 291P. The second via 292V may pass through the fourth mold layer 292. The second via 292V may be connected to each of the first connection pad 291P and the second connection pad 292P. The third via 293V may pass through a portion of the first mold layer 190. The third via 293V may be connected to each of the second connection pad 292P and the (2a)th lower pad 223a.

The second wiring structure 200 may be electrically connected to the first wiring structure 100 through the first to third connection vias 291V, 292V and 293V, the first connection pad 291P and the second connection pad 292P.

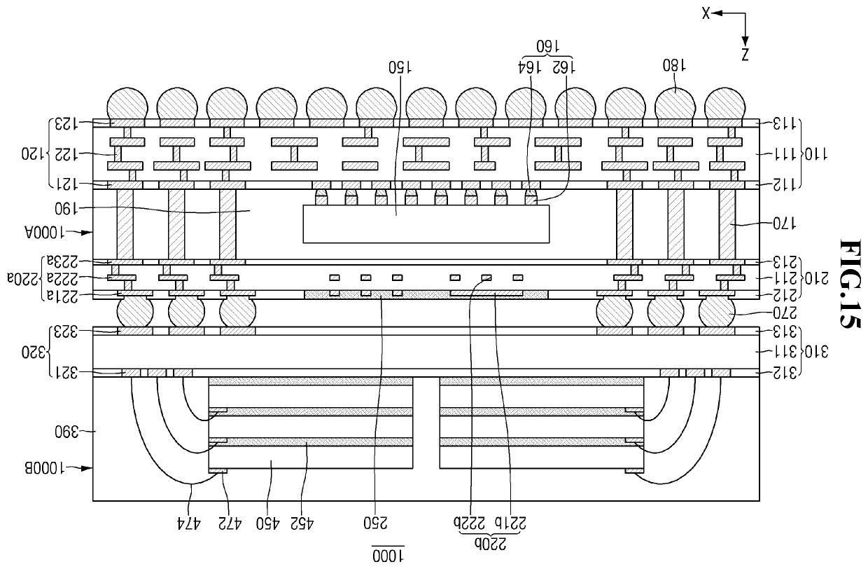

Referring to FIG. 15, the semiconductor package according to some embodiments may include third semiconductor chips 450. The third semiconductor chips 450 may have a stacked structure. The number of stacked structures and the number of semiconductor chips constituting the stacked structure may vary.

For example, the first semiconductor chip 150 may be a logic chip and the third semiconductor chips 450 may be memory chips, but embodiments are not limited thereto.

The third semiconductor chips 450 may be packaged on the third wiring structure 300 by an adhesive layer 452. The adhesive layer 452 may include, for example, at least one of a liquid epoxy, an adhesive tape, a conductive medium or their combination, but is not limited thereto.

The third semiconductor chips 450 may be electrically connected to the third wiring structure 300 by a bonding wire 474. For example, the bonding wire 474 may connect the chip pad 472 to the third upper pad 321 of the third wiring structure 300, but embodiments are not limited thereto. The third semiconductor chips 450 may be electrically connected to the third upper pad 321 by, for example, a bonding tape or the like.

Although the embodiments of the present disclosure have been described with reference to the accompanying drawings, it will be apparent to those skilled in the art that the present disclosure can be manufactured in various forms without being limited to the above-described embodiments and can be embodied in other specific forms without departing from the technical spirits and essential characteristics. Thus, the above embodiments are to be considered in all respects as illustrative and not restrictive.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a first wiring structure extending in a first direction and a second crossing the first direction;
a first semiconductor chip stacked on the first wiring structure in a third direction different from the first direction and the second direction;
a second wiring structure on the first semiconductor chip, the second wiring structure comprising an insulating layer and a first metal layer on the insulating layer; and
a marking plate on the first metal layer, the marking plate comprising a first marking region and a second marking region different from the first marking region,
wherein a shape of the first metal layer corresponding to the first marking region and a shape of the first metal layer corresponding to the second marking region are different from each other, and
wherein a shape of an uneven structure in the first marking region and a shape of an uneven structure in the second marking region are different from each other.

2. The semiconductor package of claim 1, wherein a surface roughness of the first marking region included in the marking plate is greater than a surface roughness of the second marking region.

3. The semiconductor package of claim 1, wherein the first metal layer comprises a first metal pattern below the first marking region and a second metal pattern below the second marking region in the third direction,
wherein a first convex portion is on an upper surface of the marking plate corresponding to the first metal pattern, and
wherein a second convex portion is on an upper surface of the marking plate corresponding to the second metal pattern.

4. The semiconductor package of claim 3, wherein a length of the second metal pattern is longer than a length of the first metal pattern in the first direction.

5. The semiconductor package of claim 1, wherein the first metal layer is not in the second marking region.

6. The semiconductor package of claim 1, wherein the second wiring structure further comprises a second metal layer in the insulating layer,
wherein the second metal layer comprises a third metal pattern below the first marking region and a fourth metal pattern below the second marking region in the third direction, and
wherein a third convex portion is on an upper surface of the insulating layer, which corresponds to the third metal pattern.

7. The semiconductor package of claim 6, wherein a length of the fourth metal pattern is longer than a length of the third metal pattern in the first direction.

8. The semiconductor package of claim 6, wherein the second metal layer is not in the second marking region.

9. The semiconductor package of claim 1, wherein an area of the first marking region is larger than an area of the second marking region in the first direction and the second direction.

10. The semiconductor package of claim 1, further comprising a third wiring structure and a second semiconductor chip stacked on the second wiring structure in the third direction.

11. A semiconductor package comprising:
a first wiring structure extending in a first direction and a second direction crossing the first direction;
a first semiconductor chip stacked on the first wiring structure in a third direction perpendicular to the first direction and the second direction;
a second wiring structure on the first semiconductor chip, the second wiring structure comprising an insulating layer, a first dummy metal pattern, and a second dummy metal pattern longer than the first dummy metal pattern in the first direction;
a first marking plate on the first dummy metal pattern, the first marking plate extending along a surface of the first dummy metal pattern and a surface of the insulating layer; and
a second marking plate on the second dummy metal pattern, the second marking plate extending along the surface of the second dummy metal pattern and the surface of the insulating layer,
wherein a surface roughness of the first marking plate is greater than a surface roughness of the second marking plate.

12. The semiconductor package of claim 11, wherein the second wiring structure further comprises a third dummy metal pattern and a fourth dummy metal pattern below the first dummy metal pattern and the second dummy metal pattern, respectively.

13. The semiconductor package of claim 11, wherein the first marking plate and the second marking plate comprise a metal material.

14. The semiconductor package of claim 11, wherein the first marking plate and the second marking plate comprise an insulating material.

15. The semiconductor package of claim 11, wherein the surface roughness of the first marking plate is greater than or equal to five times the surface roughness of the second marking plate.

16. The semiconductor package of claim 11, wherein a recess exposing at least a portion of the insulating layer is formed in the second wiring structure, and
wherein the first marking plate and the second marking plate are included in the recess.

17. A semiconductor package comprising a first semiconductor package and a second semiconductor package on the first semiconductor package,
wherein the first semiconductor package comprises:
a first wiring structure extending in a first direction and a second direction crossing the first direction;
a first semiconductor chip stacked on the first wiring structure in a third direction different from the first direction and the second direction;
a second wiring structure on the first semiconductor chip, the second wiring structure comprising an insulating layer, a first metal layer on the insulating layer and a second metal layer in the insulating layer; and
a marking plate on the first metal layer, the marking plate comprising a first marking region and a second marking region different from the first marking region,
wherein a shape of the first metal layer and a shape of the second metal layer corresponding to the first marking region is different from a shape of the first metal layer and a shape of the second metal layer corresponding to the second marking region, and
wherein an uneven structure of the marking plate in the first marking region and an uneven structure of the marking plate in the second marking region are different from each other.

18. The semiconductor package of claim 17, wherein the first metal layer comprises a first metal pattern and a second metal pattern respectively corresponding to the first marking region and the second marking region, and
wherein a surface of the marking plate in the first marking region has a first height difference, and a surface of the marking plate in the second marking region has a second height difference smaller than the first height difference.

19. The semiconductor package of claim 17, wherein the second metal layer comprises a third metal pattern and a fourth metal pattern respectively corresponding to the first marking region and the second marking region.

20. The semiconductor package of claim 17, wherein a surface roughness of the marking plate in the first marking region is greater than a surface roughness of the marking plate in the second marking region.
